(19) United States
(12) Patent Application Publication
(10) Pub. No.: US 2014/0231244 A1
(43) Pub. Date: Aug. 21, 2014

(54) METHOD FOR PRODUCING FILM MEMBER

(71) Applicant: TOKAI RUBBER INDUSTRIES, LTD., Komaki-shi (JP)

(72) Inventor: Kensuke Sasai, Komaki-shi (JP)

(73) Assignee: TOKAI RUBBER INDUSTRIES, LTD., Komaki-shi (JP)

(21) Appl. No.: 14/263,456

(22) Filed: Apr. 28, 2014

Related U.S. Application Data
(63) Continuation of application No. PCT/JP2012/073702, filed on Sep. 14, 2012.

(30) Foreign Application Priority Data
Nov. 18, 2011 (JP) 2011-252458

(51) Int. Cl. C23C 14/35

(52) U.S. Cl. CPC C23C 14/357
USPC 204/192.14

(57) ABSTRACT

A film member includes a substrate formed of a resin film and an aluminium oxynitride film arranged on either, front or back sides of the substrate, in which the aluminium oxynitride film is composed of 39 at % to 55 at % of Al, 7 at % to 60 at % of O, and 1 at % to 50 at % of N. A method for producing the film member includes a pressure reduction step of arranging a substrate in a chamber of a sputtering deposition system such that the substrate faces a target made of aluminium and a deposition step of introducing a source gas including nitrogen and a carrier gas into the chamber and forming the aluminium oxynitride film on a deposition surface of the substrate in an atmosphere in which a ratio of an oxygen gas pressure to a nitrogen gas pressure in the chamber is not more than 20%.

### TECHNICAL FIELD

The present invention relates to a film member that is formed by laminating a substrate formed of a resin film and a gas barrier film and does not easily allow oxygen, water vapor, and gas and volatile components included in the resin film to pass through, and a method for producing the same.

### BACKGROUND ART

With the advent of ubiquitous society, mobile equipment including mobile phones such as smart phones, portable information terminals such as personal handy-phone systems (PHSs), tablet personal computers (PCs) and mobile notebook PCs, compact game machines, and electronic paper have been widely disseminated. For such mobile equipment, there is a growing need for reduction in size and thickness, improved flexibility, and resistance to breakage due to a drop, shock or the like. In this respect, touch panels, organic electro luminescence (EL) devices, and the like that include a functional resin film formed by arranging a functional thin film on a substrate formed of a resin film have been increasingly in demand instead of glass displays frequently used at present (see, for example, Patent Documents 1 and 2). In the solar cell markets, flexible, lightweight and thin organic thin-film solar cells including functional resin films have been attracting much attention.

### PRIOR ART DOCUMENTS

### Patent Documents

Patent Document 1: Japanese Patent Application Publication No. 2009-238474 (JP 2009-238474 A)
Patent Document 2: Japanese Patent Application Publication No. 2009-178956 (JP 2009-178956 A)
Patent Document 3: Japanese Patent Application Publication No. 2005-197371 (JP 2005-197371 A)
Patent Document 4: Japanese Patent Application Publication No. 2003-301268 (JP 2003-301268 A)

### SUMMARY OF THE INVENTION

### Problem to be Solved by the Invention

Products including functional resin films, however, have a short life compared with conventional glass-substrate products. One of the reasons for this is that oxygen and water vapor in the air intrude into the functional thin film through the substrate, or gas and volatile components included in the substrate outgas to degrade the functional thin film. Another possible reason is that if the thin film under the functional thin film such as the substrate has large projections and depressions, oxygen, water vapor, and the like are adsorbed to the depressions, or electric field is concentrated on the projections, leading to degradation of the functional thin film.

A flexible organic EL device will be described by way of example. FIG. 7 shows a cross-sectional view of an organic EL device. As shown in FIG. 7, the organic EL device 7 includes a substrate 71, a front gas barrier film 72, an anode 73, a hole transport layer 74, an electron-transporting light emission layer 75, a cathode 76, and a rear gas barrier layer 77, as viewed from the front to the rear.

The light emission principle of the organic EL device 7 will be described briefly. When voltage is applied to the anode 73 and the cathode 76, holes are produced from the anode 73 and electrons are produced from the cathode 76. The holes move from the anode 73 through the hole transport layer 74 into the electron-transporting light emission layer 75. The electrons move from the cathode 76 into the electron-transporting light transmission layer 75. The holes and the electrons are combined in the electron-transporting light emission layer 75 to emit light. Here, the substrate 71, the front gas barrier film 72, the anode 73, and the hole transport layer 74 arranged in front of the electron-transporting light emission layer 75 are transparent. The emitted light therefore can be visually recognized from the front side of the organic EL device 7.

In the organic EL device 7, when oxygen and water vapor in the air intrude into the hole transport layer 74 and the electron-transporting light emission layer 75 through the substrate 71, the hole transport layer 74 and the electron-transporting light emission layer 75 are degraded. This may reduce brightness or stop light emission. The front gas barrier film 72 is therefore formed on the rear surface of the substrate 71 to suppress intrusion of oxygen and water vapor passing through the substrate 71 into the hole transport layer 74 and the electron-transporting light emission layer 75.

Known examples of the gas barrier film include silicon oxide films, silicon nitride films, and silicon oxynitride films. These films, however, do not have a satisfactory gas barrier characteristic (low transmittance characteristic for oxygen, water vapor, and outgas) and have large projections and depressions on the surface due to variations in particle diameter. It is therefore difficult to achieve a sufficient product life for practical use. The development of film members having a better gas barrier characteristic has been awaited.

The present invention is made in view of the aforementioned situation and aims to provide a film member having a good gas barrier characteristic that does not easily allow oxygen, water vapor, and outgas to pass through. The present invention also aims to provide a method for producing the film member.

### Means for Solving the Problem

(1) In order to solve the problem above, the inventor of the present invention attempted sputter deposition on a substrate formed of a resin film using a relatively inexpensive aluminium (Al) as a target. As a result of intensive experiments, the inventor has found that by forming an aluminium oxynitride film (AlON film) having a certain composition range on the substrate, an extremely high gas barrier characteristic can be achieved. A film member according to the present invention made based on this finding is characterized by including: a substrate formed of a resin film; and an aluminium oxynitride (AlON) film arranged on at least one of a front side and a back side of the substrate, in which the aluminium oxynitride film is composed of 39 at % to 55 at % of Al, 7 at % to 60 at % of O, and 1 at % to 50 at % of N (not less than 39 at % and not more than 55 at % of aluminium atoms, not less than 7 at % and not more than 60 at % of oxygen atoms, and not less than 1 at % and not more than 50 at % of nitrogen atoms).

The low transmittance characteristic for oxygen, water vapor, and outgas is significantly improved by arranging the AlON film having the above-noted composition range on the substrate formed of a resin film. The film member of the present invention therefore can be used to suppress intrusion of oxygen, water vapor, and outgas into the hole transport layer and the electron-transporting light emission layer, for example, in an organic EL device. Accordingly, degradation of the hole transport layer and the electron-transporting light emission layer can be suppressed. As a result, the product life can be prolonged.

(2) A method for producing a film member according to the present invention for producing the film member of the above configuration (1) is characterized by including: a pressure reduction step of arranging the substrate in a chamber of a sputtering deposition system such that the substrate faces a target made of aluminium and exhausting gas in the chamber to maintain a predetermined vacuum level in the chamber; and a deposition step of introducing a source gas including nitrogen and a carrier gas into the chamber and sputtering the target with plasma generated by ionization of the carrier gas at a predetermined vacuum level in an atmosphere in which a ratio of an oxygen gas pressure to a nitrogen gas pressure in the chamber is not more than 20% to form the aluminium oxynitride film on a deposition surface of the substrate.

In the method for producing a film member according to the present invention, deposition by sputtering is performed in an atmosphere in which the ratio of the oxygen gas pressure to the nitrogen gas pressure in the chamber is not more than 20%. That is, the composition of the source gas actually present in the chamber during deposition is important rather than the flow rate of the source gas introduced into the chamber. The composition of the gas in the chamber can be analyzed, for example, with a quadrupole mass spectrometer with differential pumping. Sputtering can be performed in an atmosphere in which the ratio (P_{O2}/P_{N2}×100) of the oxygen gas pressure (P_{O2}) to the nitrogen gas pressure (P_{N2}) is not more than 20%. A more preferable ratio of the oxygen gas pressure is not more than 19.1%. With this, an AlON film having the composition range of 39 at % to 55 at % of Al, 7 at % to 60 at % of O, and 1 at % to 50 at % of N can be formed on the deposition surface of the substrate formed of a resin film.

(3) Preferably, in the above configuration (2), the sputtering deposition system includes the target and magnetic field forming means for forming a magnetic field on a surface of the target, and generates the plasma by magnetron discharge.

Deposition by sputtering includes diode sputtering and magnetron sputtering. Among those, in magnetron sputtering, secondary electrons emitted from the target are captured by the magnetic field produced on the target surface. The temperature of the substrate therefore does not easily increase. In addition, the captured secondary electrons promote ionization of gas, thereby increasing the deposition rate. The sputtering deposition system of this configuration employs magnetron sputtering. The sputtering deposition system in this method thus can form an AlON film relatively quickly while a thermal deformation of the substrate is small. The sputtering deposition system in this method preferably employs DC (Direct Current) magnetron sputtering (including DC pulse type).

(4) Preferably, in the above configuration (3), the sputtering deposition system further includes an ECR plasma generator. The ECR plasma generator includes a rectangular waveguide that transmits microwaves, a slot antenna arranged on one surface of the rectangular waveguide and having a slot through which the microwaves pass, a dielectric section arranged so as to cover the slot of the slot antenna and having a front surface on a plasma generation region side parallel to an incident direction of the microwaves from the slot, a support plate arranged on a back surface of the dielectric section for supporting the dielectric section, and a permanent magnet arranged on a back surface of the support plate for forming a magnetic field in the plasma generation region. Plasma is generated while electron cyclotron resonance (ECR) is produced with the microwaves propagating from the dielectric section into the magnetic field. In the deposition step, sputtering is preferably performed with ECR plasma applied between the substrate and the target.

In a sputtering deposition system that performs deposition by DC magnetron sputtering, a negative high voltage of several hundred volts is required to be applied to the target in order to stabilize the generated plasma and increase the deposition rate. Argon ions generated by magnetron discharge are further accelerated and collide against the target. Neutral particles having a relatively large particle diameter are emitted from the target and deposited on the substrate. In particular, when the applied voltage is high, particles having a very large particle diameter such as cluster particles are emitted from the target more frequently. When the particles having large particle diameters that vary widely are deposited on the substrate, projections and depressions are produced on the surface of the formed AlON film. When the projections and depressions on the surface of the AlON film are large, oxygen and other substances are likely to be adsorbed to the depressions. This may degrade the AlON film itself or degrade the counterpart material in contact with the AlON film. The projections may also degrade the counterpart material. For example, in organic EL devices, if the projections and depressions on the surface of the AlON film are large, the anode formed on that surface also has large projections and depressions. The electric field is then concentrated on the projections of the anode, which influences the electron-transporting light emission layer so that the electron-transporting light emission layer is degraded, possibly stopping light emission.

In order to solve these problems, the inventor of the present invention has made intensive studies to find that it is possible to reduce the applied voltage and to ionize or miniaturize the emitted neutral particles thereby achieving a uniform particle diameter, by performing deposition with plasma generated by magnetron discharge (hereinafter called “magnetron plasma” as appropriate) while applying microwave plasma. However, in order to suppress intrusion of impurities and maintain the film quality, magnetron sputtering is generally performed under a certain low pressure in which magnetron plasma is stable. The pressure during deposition is preferably about 0.5 Pa to 1.0 Pa. General microwave plasma generators, however, generate microwave plasma under relatively high voltages of 5 Pa or more (see, for example, Patent Document 3). It is therefore difficult for conventional microwave plasma generators to generate microwave plasma under a low pressure of not more than 1 Pa at which magnetron sputtering is performed. The directivity of microwave plasma is also lacking. The possible reason for this is as follows.

FIG. 4 shows a perspective view of a microwave plasma generation unit in a conventional microwave plasma generator. As shown in FIG. 4, the microwave plasma generator 9 includes a waveguide 90, a slot antenna 91, and a dielectric section 92. The slot antenna 91 is arranged so as to cover the front opening of the waveguide 90. That is, the slot antenna 91 forms a front wall of the waveguide 90. The slot antenna 91 has a plurality of long hole-shaped slots 910. The dielectric section 92 is arranged on the front surface (chamber side) of the slot antenna 91 so as to cover the slots 910. Microwaves transmitted from the right end of the waveguide 90 pass through the slots 910 to be incident on the dielectric section 92 as shown by white arrows Y1 in the front-rear direction in the figure. The microwaves incident on the dielectric section 92 propagate along the front surface 920 of the dielectric section 92 as shown by a white arrow Y2 in the left-right direction in the figure. Microwave plasma P is thus generated.

Here, the incident direction (the arrows Y1) of microwaves incident on the dielectric section 92 from the slots 910 is orthogonal to the front surface 920 of the dielectric section 92. Accordingly, the microwaves incident on the dielectric section 92 are interrupted by the generated microwave plasma P, and propagate along the front surface 920 of the dielectric section 92 (the arrow Y2) after the travelling direction thereof is changed by 90°. Thus, the plasma source microwaves do not easily propagate into the microwave plasma P because the microwaves are incident perpendicularly to the generated microwave plasma P. Therefore, the plasma generation under low pressure is considered to be difficult.

The inventor of the present invention then has focused attention on the incident direction of microwaves relative to the generated microwave plasma and developed an ECR plasma generator that can generate high-density plasma even under a low pressure of not more than 1 Pa by using electron cyclotron resonance (ECR). More specifically, the ECR plasma generator according to the present invention includes a rectangular waveguide that transmits microwaves, a slot antenna arranged on one surface of the rectangular waveguide and having a slot through which the microwaves pass, a dielectric section arranged so as to cover the slot of the slot antenna and having a front surface on a plasma generation region side parallel to an incident direction of the microwaves from the slot, a support plate arranged on a back surface of the dielectric section for supporting the dielectric section, and a permanent magnet arranged on a back surface of the support plate for forming a magnetic field in the plasma generation region. Plasma is generated while producing ECR with the microwaves propagating from the dielectric section into the magnetic field. In the ECR plasma generator of the present invention, the surface on the plasma generation region side is called “front surface” and the surface opposite the front surface is called “back surface.”

FIG. 3 shows a perspective view of a microwave plasma generation unit in the ECR plasma generator of the present invention. FIG. 3 is a diagram showing an embodiment of the microwave plasma generation unit (see the embodiment described later). FIG. 3 does not limit the ECR plasma generator of the present invention.

As shown in FIG. 3, the microwave plasma generation unit 40 includes a waveguide 41, a slot antenna 42, a dielectric section 43, a support plate 44, and a permanent magnet 45. A tubular section 51 transmitting microwaves is connected to the rear side of the left end of the waveguide 41. The slot antenna 42 is arranged so as to close the upper opening of the waveguide 41. That is, the slot antenna 42 forms the top wall of the waveguide 41. The slot antenna 42 has a plurality of long hole-shaped slots 420. The dielectric section 43 is arranged on the top surface of the slot antenna 42 so as to cover the slots 420.

Microwaves transmitted from the tubular section 51 pass through the slots 420 to be incident on the dielectric section 43 as shown by the white arrows Y1 in the top-bottom direction in the figure. The microwaves incident on the dielectric section 43 mainly propagate along the front surface 430 of the dielectric section 43 as shown by the white arrow Y2 in the left-right direction in the figure. Microwave plasma is thus generated. Here, the incident direction of microwaves incident on the dielectric section 43 from the slots 420 is parallel to the front surface 430 (the surface on the plasma generation region side) of the dielectric section 43. The plasma source microwaves more easily propagate into the microwave plasma because the microwaves are incident along the generated microwave plasma.

Eight permanent magnets 45 are arranged on the rear side of the dielectric section 43 with the support plate 44 interposed therebetween. The eight permanent magnets 45 each have the north pole on the front side and the south pole on the rear side. Magnetic lines of force M are produced frontward from the permanent magnets 45. A magnetic field is thus formed in front of the dielectric section 43 (plasma generation region).

Electrons in the generated microwave plasma make a spinning movement clockwise relative to the magnetic lines of force M in accordance with the cyclotron angular frequency ω_{ce}. Microwaves propagating in the microwave plasma excite clockwise circular polarization, which is called electron cyclotron waves. The electron cyclotron waves propagate forward, and when their angular frequency ω agrees with the cyclotron angular frequency ω_{ce}, the electron cyclotron waves attenuate and the wave energy is absorbed by electrons. That is, ECR is produced. For example, when the frequency of microwaves is 2.45 GHz, ECR is produced at a magnetic flux density of 0.0875 T. The electrons having energy increased by ECR collide with the surrounding neutral particles while being bound by the magnetic lines of force M. The neutral particles are thus ionized one after another. The electrons produced by the ionization are also accelerated by ECR and further ionize neutral particles. High-density ECR plasma P1 is thus generated in front of the dielectric section 43.

Thus, the ECR plasma generator according to the present invention can generate plasma under a low pressure of not more than 1 Pa, or even under an extremely low pressure of not more than 0.1 Pa, by launching microwaves along the generated microwave plasma and increasing the plasma density using ECR. Accordingly, the ECR plasma generator of the present invention makes it possible to carry out deposition with magnetron plasma while applying ECR plasma under low pressure.

As described above, the sputtering deposition system of this configuration performs deposition with magnetron plasma while applying ECR plasma. The application of ECR plasma between the substrate and the target can keep magnetron plasma stable even when the applied voltage is reduced. This can suppress emission of particles having an extremely large particle diameter such as cluster particles from the target. As a result, variations in particle diameter of the sputtering particles can be suppressed, and the projections and depressions on the surface of the formed AlON film can be reduced. In addition, the application of ECR plasma can miniaturize the sputtering particles. Accordingly, an AlON film can be formed with even smaller particles, and a fine-grained AlON film can be formed.

As described above, the ECR plasma generator of the present invention can generate plasma under a low pressure of not more than 1 Pa, or even under an extremely low pressure of not more than 0.1 Pa. Magnetron sputtering performed under lower pressure can suppress intrusion of impurities and increase the mean free path of the target particles. Accordingly, the film quality of the formed AlON film can be improved.

Patent Document 4 discloses a magnetron sputtering deposition system using ECR. In the magnetron sputtering deposition system in Patent Document 4, magnets are arranged on the back side of a substrate subjected to deposition, and ECR plasma is generated in the vicinity of the front surface of the substrate. The arrangement of magnets on the back side of the substrate, however, is likely to cause variations in thickness of the formed thin film. In addition, the thin film is likely to be colored. In the magnetron sputtering deposition system in Patent Document 4, microwaves are radiated from a helical antenna. The microwaves therefore do not easily propagate uniformly throughout the plasma generation region. There is no directivity from the antenna to the plasma generation region by the magnetic field, so that the substrate is heated by the microwaves and may be thermally deformed.

In this respect, in the ECR plasma generator according to the present invention, permanent magnets are arranged on the back surface side of the dielectric section to allow microwaves to propagate along the front surface of the dielectric section. In other words, permanent magnets are not arranged in the vicinity of the substrate. Accordingly, the problems with the magnetron sputtering deposition system in Patent Document 4 do not occur.

(4-1) Preferably, in the above configuration (4), the support plate may have cooling means for suppressing a temperature increase of the permanent magnet.

The permanent magnet is arranged on the back surface side of the dielectric section with the support plate being interposed therebetween. Accordingly, when plasma is generated, the temperature of the permanent magnet tends to increase. When the temperature of the permanent magnet reaches the Curie temperature or higher, the magnetism is significantly reduced. According to the present method, the cooling means for the support plate suppresses temperature increase of the permanent magnet. The magnetism of the permanent magnet is less likely to decrease. Accordingly, the present configuration allows formation of a stable magnetic field.

(4-2) Preferably, in the above configuration (4), the deposition step may be performed under a pressure of not less than 0.05 Pa and not more than 3 Pa.

A high vacuum level of not less than 0.05 Pa and not more than 3 Pa inside the chamber can stabilize the generated plasma, suppress intrusion of impurities, and increase the mean free path of the target particles. Accordingly, the film quality of the formed AlON film is improved.

### BRIEF DESCRIPTION OF THE DRAWINGS

FIG. 1 is a cross-sectional view taken along the left-right direction of a magnetron sputtering deposition system.

FIG. 2 is a cross-sectional view taken along the front-rear direction of the magnetron sputtering deposition system.

FIG. 3 is a perspective view of a microwave plasma generation unit in an ECR plasma generator included in the magnetron sputtering deposition system.

FIG. 4 is a perspective view of a microwave plasma generation unit in a conventional microwave plasma generator.

FIG. 5 is an SPM image of an AlON film in a film member in Example 1.

FIG. 6 is an SPM image of an AlON film in a film member in Reference Example.

FIG. 7 is a cross-sectional view of an organic EL device.

### DESCRIPTION OF THE REFERENCE NUMERALS

1: magnetron sputtering deposition system (sputtering deposition system).
20: substrate, 21: substrate support member, 210: table, 211: leg.
3: sputtering unit, 30: target, 31: backing plate, 32a to 32c: permanent magnet (magnetic field forming means), 33: cathode, 34: ground shield, 35: DC pulse power source.
4: ECR plasma generator, 40: microwave plasma generation unit, 41: waveguide (rectangular waveguide), 42: slot antenna, 43: dielectric section, 44: support plate, 45: permanent magnet, 420: slot, 430: front surface, 440: refrigerant path (cooling means), 441: cooling tube, 50: microwave transmission unit, 51: tubular section, 52: microwave power source, 53: microwave oscillator, 54: isolator, 55: power monitor, 56: EH matcher.
8: chamber, 80: carrier gas supply port, 81: first gas supply port, 82: second gas supply port, 83: exhaust port, 84: gas analysis port, 85: mass spectrometer.
M: magnetic line of force, P1: ECR plasma, P2: magnetron plasma.

### MODES FOR CARRYING OUT THE INVENTION

Embodiments of a film member and a method for producing the same according to the present invention will be described below.

### <Film Member>

The film member according to the present invention includes a substrate formed of a resin film and an AlON film arranged on at least one of the front and back sides of the substrate and composed of 39 at % to 55 at % of Al, 7 at % to 60 at % of O, and 1 at % to 50 at % of N.

The substrate may be selected as appropriate depending on applications. Examples of the substrate include polyethylene terephthalate (PET) films, polyethylene naphthalate (PEN) films, polyphenylenesulfide (PPS) films, polyamide (PA) 6 films, PA 11 films, PA 12 films, PA 46 films, polyamide MXD6 films, PA 9T films, polyimide (PI) films, polycarbonate (PC) films, fluoropolymer films, ethylene-vinylalcohol copolymer (EVOH) films, polyvinyl alcohol (PVA) films, and polyethylene (PE), polypropylene (PP), cycloolefin polymer, and other polyolefin films. Among those, PET films and PEN films are preferred in view of their moisture absorption resistance, colorlessness and transparency, heat resistance, cost efficiency, and so forth. A hard coat layer of, for example, an acrylic resin coating may be formed on at least one of the front and back surfaces of the film. The hard coat layer can reduce the effects of projections and depressions on the surface of the film itself. For example, a PET film having a hard coat layer (HC-PET film) is preferred.

The AlON film may be arranged on only one of the front and back sides of the substrate or may be arranged on both sides of the substrate. The AlON film arranged on the functional thin film side can enhance the low transmittance characteristic for oxygen, water vapor, and outgas. The AlON film arranged on both of the front and back sides of the substrate can further improve the low transmittance characteristic for oxygen and water vapor. The thickness of the AlON film is preferably, but not limited to, not less than 10 nm and not more than 1 μm, for example, for the use in organic EL devices. When the thickness of the AlON film is less than 10 nm, it is difficult to achieve the desired gas barrier characteristic. When the thickness of the AlON film exceeds 1 μm, the AlON film is likely to be cracked and is inferior in cost efficiency. In the case where the AlON film is arranged on both of the front and back sides of the substrate, the thickness of the AlON film may be varied between the front side and the back side.

The AlON film may be arranged directly on the front surface and/or the back surface of the substrate or may be arranged indirectly with an intermediate layer such as an adhesive layer interposed therebetween. An intermediate layer interposed between the substrate and the AlON film improves the adhesiveness between the substrate and the AlON film, the gas barrier characteristic, the smoothness of the AlON film, and so forth. Only one intermediate layer may be provided, or alternatively, two or more intermediate layers may be provided. The intermediate layer can be formed by coating the substrate, for example, with an acrylic resin or an isocyanate. Alternatively, the intermediate layer can be formed by depositing a metal alkoxide such as an alkoxysilane or a titanate, a silane coupling agent, a chlorosilane, a silazane, or the like by coating or CVD (Chemical Vapor Deposition). Alternatively, the intermediate layer can be formed by depositing a hydrocarbon such as acetylene, methane, or toluene by CVD. Among those, coating of a titanate and a silazane and CVD of an alkoxysilane, acetylene, methane, or the like are preferred because they can improve smoothness and heat resistance and impart the gas barrier characteristic.

The AlON film is composed of 39 at % to 55 at % of Al, 7 at % to 60 at % of O, and 1 at % to 50 at % of N. For example, when the proportion of the number of oxygen atoms (O) exceeds 60%, the low transmittance characteristic for oxygen, water vapor, and outgas is poor. When the proportion of the number of oxygen atoms is less than 7%, the flexibility is reduced, and the AlON film is more likely to be cracked and is colored. Similarly, when the proportion of the number of aluminium (Al) atoms exceeds 55%, gray or metallic color is developed. When the proportion of the number of aluminium atoms is less than 39%, the low transmittance characteristic for oxygen, water vapor, and outgas is poor.

The particle diameter of AlON that constitutes the AlON film is not particularly limited. However, if the particle diameter of AlON is large, projections and depressions are likely to be produced on the surface of the AlON film. In this case, for example, oxygen and the like are adsorbed to the depressions, possibly causing degradation of the AlON film and the counterpart material. The projections may also degrade the counterpart material. The particle diameter of AlON is therefore preferably not more than 150 nm.

The particle diameter of AlON may be measured by observing the surface or the cross section of the AlON film with a scanning probe microscope (SPM). In this description, the maximum length of AlON particles in the captured SPM image is considered as the particle diameter.

Similarly, the surface roughness of the AlON film is preferably such that the arithmetic mean roughness (Ra) is not more than 3 nm and the maximum height (Rz) is not more than 30 nm because it is preferable that projections and depressions on the surface of the AlON film be small. The surface roughness can be measured in accordance with JIS B0601: 2001.

<Method for Producing Film Member>

[System Configuration]

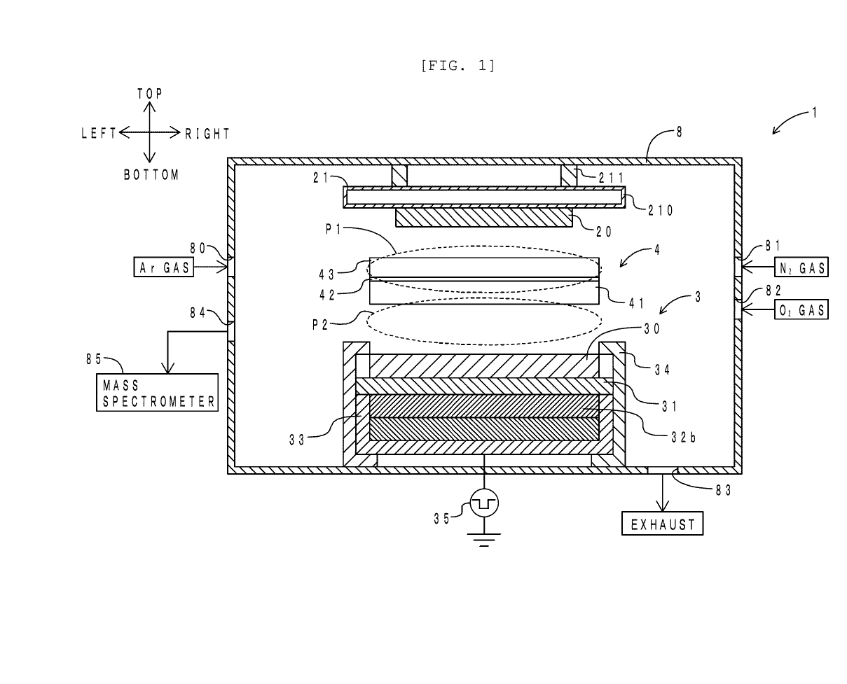

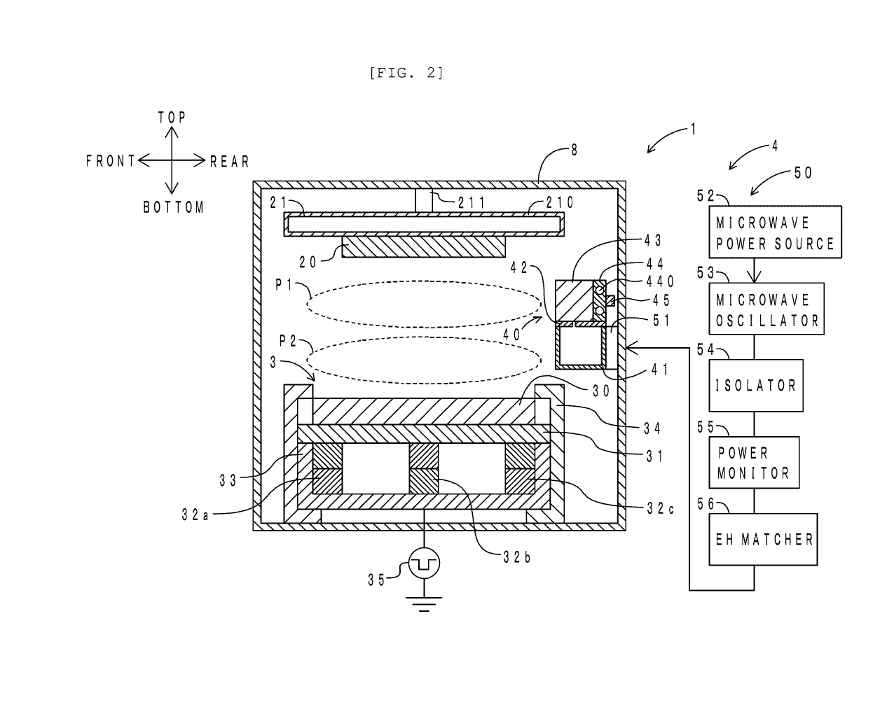

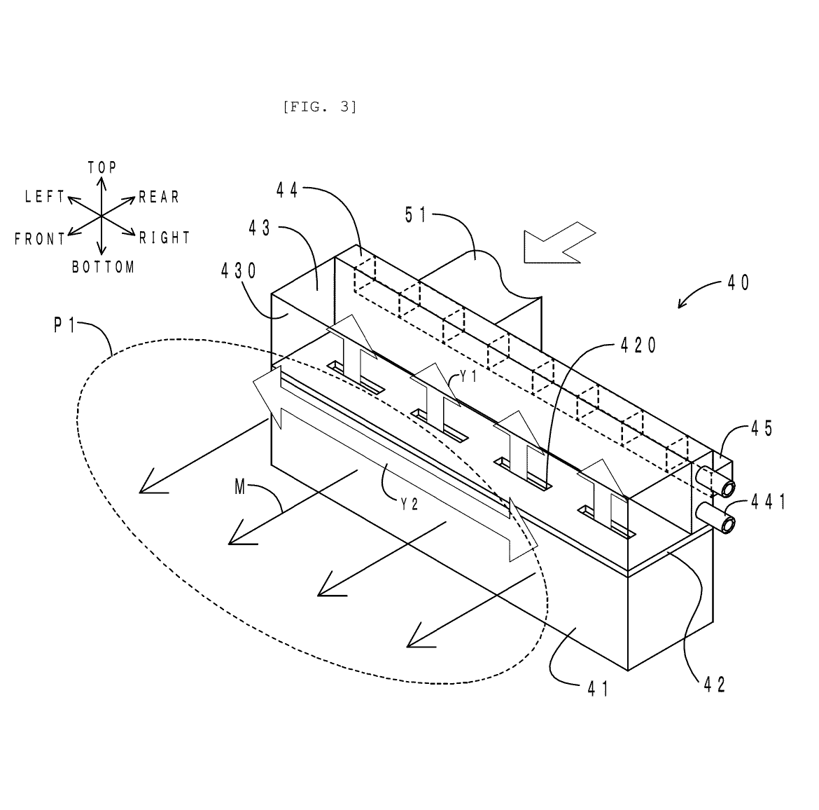

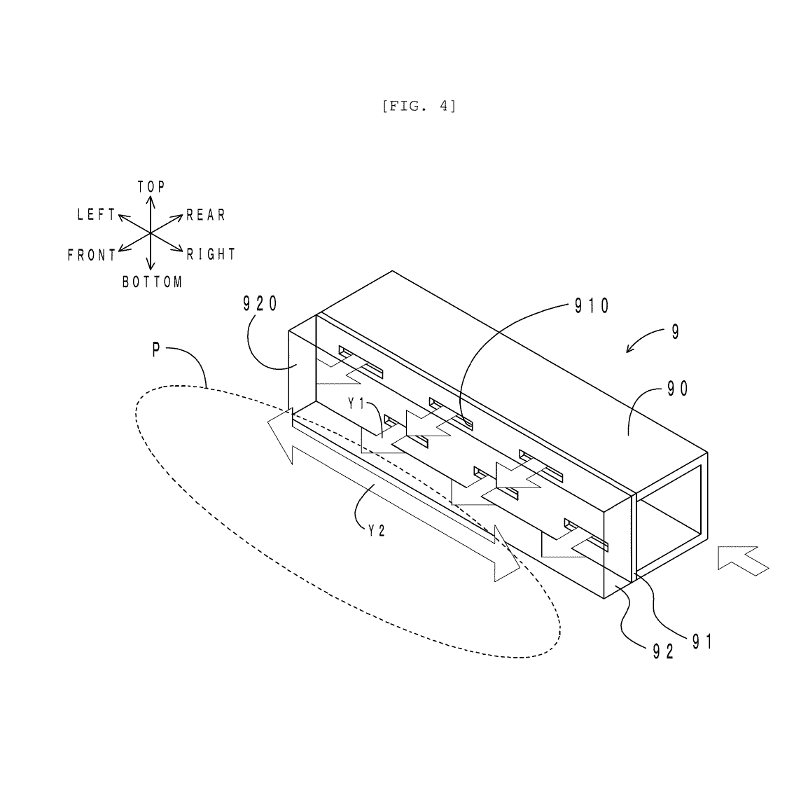

First, an embodiment of the sputtering deposition system for producing the film member according to the present invention will be described. FIG. 1 is a cross-sectional view taken along the left-right direction of the magnetron sputtering deposition system in the present embodiment. FIG. 2 is a cross-sectional view taken along the front-rear direction of the magnetron sputtering deposition system. FIG. 3 is a perspective view of the microwave plasma generation unit in the ECR plasma generator included in the magnetron sputtering deposition system.

As shown in FIG. 1 to FIG. 3, the magnetron sputtering deposition system 1 includes a chamber 8, a substrate support member 21, a sputtering unit 3, and an ECR plasma generator 4.

The chamber 8 is made of aluminium and has the shape of a rectangular box. A carrier gas supply port 80 and a gas analysis port 84 are formed in the left wall of the chamber 8. To the carrier gas supply port 80, a downstream end (not shown) of a gas supply tube for supplying argon (Ar) gas into the chamber 8 is connected. To the gas analysis port 84, a mass spectrometer 85 with differential pumping (with a turbomolecular pump and a rotary pump) for analyzing gas in the chamber 8 is connected. A first gas supply port 81 and a second gas supply port 82 are formed in the right wall of the chamber 8. To the first gas supply port 81, a downstream end of a gas supply tube (not shown) for supplying nitrogen (N₂) gas into the chamber 8 is connected. Similarly, to the second gas supply port 82, a downstream end of a gas supply tube (not shown) for supplying oxygen (O₂) gas into the chamber 8 is connected. An exhaust port 83 is formed in the bottom wall of the chamber 8. To the exhaust port 83, an evacuator (not shown) for exhausting gas in the chamber 8 is connected.

The substrate support member 21 has a table 210 and a pair of legs 211. The table 210 is made of stainless steel and has the shape of a hollow rectangular plate. The inside of the table 210 is filled with coolant. The coolant is circulated to cool the table 210. The pair of legs 211 is arranged on the top surface of the table 210 so as to be spaced apart from each other in the left-right direction. Each of the pair of legs 211 is made of stainless steel and has the shape of a cylinder. The outer peripheral surface of each of the pair of legs 211 is coated with an insulating layer. The table 210 is attached to the top wall of the chamber 8 with the pair of legs 211 interposed therebetween.

The sputtering unit 3 includes a target 30, a backing plate 31, permanent magnets 32a to 32c, and a cathode 33. The cathode 33 is made of stainless steel and has the shape of a rectangular box open upward. A ground shield 34 is arranged to surround the cathode 33, the target 30, and the backing plate 31. The cathode 33 is arranged on the bottom surface of the chamber 8 with the ground shield 34 interposed therebetween. The cathode 33 is connected to a DC pulse power source 35.

The permanent magnets 32a to 32c are arranged inside the cathode 33. The permanent magnets 32a to 32c are each shaped like an elongated rectangular parallelepiped. The permanent magnets 32a to 32c are arranged so as to be spaced apart in the front-rear direction and parallel to each other. The permanent magnet 32a and the permanent magnet 32c each have the south pole on the top side and the north pole on the bottom side. The permanent magnet 32b has the north pole on the top side and the south pole on the bottom side. The permanent magnets 32a to 32c form a magnetic field on the top surface of the target 30. The permanent magnets 32a to 32c are included in the magnetic field forming means in the present invention.

The backing plate 31 is made of copper and has the shape of a rectangular plate. The backing plate 31 is arranged so as to cover the upper opening of the cathode 33.

The target 30 is made of aluminium and has the shape of a rectangular thin plate. The target 30 is arranged on the top surface of the backing plate 31. The target 30 is arranged so as to face the table 210.

The ECR plasma generator 4 includes a microwave plasma generation unit 40 and a microwave transmission unit 50. The microwave transmission unit 50 has a tubular section 51, a microwave power source 52, a microwave oscillator 53, an isolator 54, a power monitor 55, and an EH matcher 56. The microwave oscillator 53, the isolator 54, the power monitor 55, and the EH matcher 56 are coupled through the tubular section 51. The tubular section 51 is connected to the rear side of the waveguide 41 of the microwave plasma generation unit 40 through a waveguide hole formed in the rear wall of the chamber 8.

The microwave plasma generation unit 40 has a waveguide 41, a slot antenna 42, a dielectric section 43, a support plate 44, and a permanent magnet 45. As shown in FIG. 3, the waveguide 41 is made of aluminium and has the shape of a rectangular box open upward. The waveguide 41 extends in the left-right direction. The waveguide 41 is included in the rectangular waveguide in the present invention. The slot antenna 42 is made of aluminium and has the shape of a rectangular plate. The slot antenna 42 closes the opening of the waveguide 41 from above. In other words, the slot antenna 42 forms the top wall of the waveguide 41. The slot antenna 42 has four slots 420. The slots 420 each have the shape of a long hole extending in the left-right direction. The slots 420 are each arranged at a place where the magnetic field is strong.

The dielectric section 43 is made of quartz and has the shape of a rectangular parallelepiped. The dielectric section 43 is arranged on the front side of the top surface of the slot antenna 42. The dielectric section 43 covers the slots 420 from above. As previously mentioned, the front surface 430 of the dielectric section 43 is arranged parallel to the incident direction Y1 of the microwaves from the slots 420. The front surface 430 is included in the front surface on the plasma generation region side of the dielectric section.

The support plate 44 is made of stainless steel and has the shape of a flat plate. The support plate 44 is arranged in contact with the rear surface (back surface) of the dielectric section 43 on the top surface of the slot antenna 42. A refrigerant path 440 is formed inside the support plate 44. The refrigerant path 440 has the shape of a letter U extending in the left-right direction. The right end of the refrigerant path 440 is connected to a cooling tube 441. The refrigerant path 440 is connected to a heat exchanger and a pump (both not shown) outside the chamber 8 through the cooling tube 441. The coolant is circulated through the refrigerant path 440, the cooling tube 441, the heat exchanger, the pump, the cooling tube 441, and again, the refrigerant path 440. The circulation of the coolant cools the support plate 44. The refrigerant path 440 and the coolant are included in the cooling means in the present invention.

The permanent magnet 45 is a neodymium magnet and has the shape of a rectangular parallelepiped. Eight permanent magnets 45 are arranged on the rear surface (back surface) of the support plate 44. The eight permanent magnets 45 are arranged in series continuously in the left-right direction. The eight permanent magnets 45 each have the north pole on the front side and the south pole on the rear side. Magnetic lines of force M are produced frontward from the permanent magnets 45. A magnetic field is thus formed in the plasma generation region in front of the dielectric section 43.

[Production Method]

The method for producing a film member using the magnetron sputtering deposition system 1 will now be described. The method for producing a film member in the present embodiment includes a pressure reduction step and a deposition step. In the pressure reduction step, first, a substrate 20 is arranged on the bottom surface of the table 210 in the chamber 8. The substrate 20 is an HC-PET film and has a rectangular shape. Here, the substrate 20 is placed such that the deposition surface thereof faces downward. That is, the deposition surface of the substrate 20 faces the top surface of the target 30. Next, the evacuator (not shown) is operated to exhaust gas inside the chamber 8 from the exhaust port 83 to bring the inside of the chamber 8 into a reduced pressure state of about 0.015 Pa.

In the deposition step, first, Ar gas serving as a carrier gas is supplied into the chamber 8. Subsequently, N₂ gas serving as a source gas is supplied into the chamber 8. The pressure in the chamber 8 is thereby set at about 0.7 Pa. Here, the gas composition in the chamber 8 is monitored with the mass spectrometer 85. The flow rate of the N₂ gas is regulated appropriately so that the ratio (P_{O2}/P_{N2}×100) of the O₂ gas pressure (P_{O2}) to the N₂ gas pressure (P_{N2}) is 18.1%. O₂ gas serving as the source gas is supplied into the chamber 8 as necessary.

Next, the microwave power source 52 is turned on. The turning on of the microwave power source 52 allows the microwave oscillator 53 to generate microwaves at a frequency of 2.45 GHz. The generated microwaves propagate in the tubular section 51. Here, the isolator 54 suppresses the microwaves reflected from the microwave plasma generation unit 40 from returning to the microwave oscillator 53. The power monitor 55 monitors the output of the generated microwaves and the output of the reflected microwaves. The EH matcher 56 regulates the amount of reflection of microwaves. The microwaves passing through the tubular section 51 propagate in the waveguide 41. The microwaves propagating in the waveguide 41 enter the slots 420 of the slot antenna 42. As shown by the white arrows Y1 in FIG. 3, the microwaves pass through the slots 420 and are incident on the dielectric section 43. The microwaves incident on the dielectric section 43 mainly propagate along the front surface 430 of the dielectric section 43 as shown by the white arrow Y2 in the figure. The strong electric field of the microwaves ionizes the argon gas in the chamber 8, whereby microwave plasma is generated in front of the dielectric section 43.

The electrons in the generated microwave plasma each make a spinning movement clockwise relative to the magnetic lines of force M in accordance with the cyclotron angular frequency. The microwaves propagating in the microwave plasma excite electron cyclotron waves. The angular frequency of the electron cyclotron waves agrees with the cyclotron angular frequency at a magnetic flux density of 0.0875 T. ECR is thereby produced. The electrons having energy increased by ECR collide with the surrounding neutral particles while being bound by the magnetic lines of force M. The neutral particles are thus ionized one after another. The electrons produced by the ionization are also accelerated by ECR and further ionize the neutral particles. High-density ECR plasma P1 is thus generated in front of the dielectric section 43.

Next, the DC pulse power source 35 is turned on to apply voltage to the cathode 33. Magnetron discharge thus produced ionizes the argon gas to generate magnetron plasma P2 above the target 30. The target 30 is then sputtered with the magnetron plasma P2 (argon ion) to eject sputtering particles from the target 30. The sputtering particles emitted from the target 30 scatter toward the substrate 20 while reacting with N₂ gas and O₂ gas and adhere onto the bottom surface of the substrate 20 to form an AlON film. Here, ECR plasma P1 is applied between the substrate 20 and the target 30 (including the magnetron plasma P2 generation region). The film member is thus produced.

[Operation Effects]

The operation effects of the method for producing a film member in the present embodiment will now be described. In the production method of the present embodiment, an AlON film is formed by sputtering in an atmosphere in which the ratio of the O₂ gas pressure to the N₂ gas pressure in the chamber 8 is not more than 20%. Accordingly, an AlON film composed of 39 at % to 55 at % of Al, 7 at % to 60 at % of O, and 1 at % to 50 at % of N can be easily formed on the bottom surface of the substrate 20.

The magnetron sputtering deposition system 1 can form an AlON film relatively quickly while a thermal deformation of the substrate 20 is small. The magnetron sputtering deposition system 1 performs sputtering deposition with magnetron plasma P2 while applying ECR plasma P1. The application of ECR plasma P1 between the substrate 20 and the target 30 can keep magnetron plasma P2 stable even when the applied voltage is reduced. This can suppress ejection of particles having a relatively large particle diameter such as cluster particles from the target 30. As a result, variations in particle diameter of sputtering particles can be suppressed, and projections and depressions on the surface of the formed AlON film can be reduced. In addition, the application of ECR plasma P1 miniaturizes the sputtering particles. An AlON film therefore can be formed with smaller particles, and a fine-grained AlON film can be formed. Accordingly, the magnetron sputtering deposition system 1 can form an AlON film having a surface roughness of not more than 3 nm of Ra and not more than 30 nm of Rz, with the particle diameter of AlON not more than 150 nm.

The ECR plasma generator 4 can generate ECR plasma P1 even under a low pressure of not more than 1 Pa by launching microwaves along the generated microwave plasma and increasing the plasma density using ECR. The generation of ECR plasma P1 and the deposition by magnetron sputtering therefore can be performed with the inside of the chamber 8 in a high vacuum state of 0.7 Pa. This can stabilize magnetron plasma P2, suppress intrusion of impurities, and increase the mean free path of the target particles. Accordingly, the film quality of the formed AlON film is improved.

In the ECR plasma generator 4, the waveguide 41 has the shape of an elongated box extending in the left-right direction. The slots 420 are arranged in series in the left-right direction. The ECR plasma generator 4 therefore can generate ECR plasma P1 in an elongated shape. Accordingly, the magnetron sputtering deposition system 1 can form an elongated, large-area AlON film. Eight permanent magnets 45 are arranged on the rear side of the dielectric section 43. Microwaves are propagated in the magnetic field formed in front of the dielectric section 43. Accordingly, the microwaves easily propagate uniformly throughout the plasma generation region. The eight permanent magnets 45 are arranged on the rear surface of the support plate 44. The refrigerant path 440 is formed inside the support plate 44. Coolant is circulated through the refrigerant path 440 to cool the support plate 44. The temperature of the permanent magnets 45 therefore does not easily increase. Accordingly, the magnetism of the permanent magnets 45 is less likely decrease due to temperature increase. A stable magnetic field is therefore formed even during plasma generation.

[Others]

An embodiment of the method for producing a film member according to the present invention has been described above. However, the method for producing a film member according to the present invention is not limited to the foregoing embodiment. Various modifications and improvements can be made by those skilled in the art.

For example, in the foregoing embodiment, the magnetron sputtering deposition system is used as a sputtering deposition system. However, the sputtering deposition system may be a system that performs sputtering without forming a magnetic field (for example, diode sputtering system). ECR plasma is not necessarily applied during deposition. That is, the sputtering deposition system may be configured without the ECR plasma generator.

In the foregoing embodiment, the gas composition in the chamber is adjusted so that the ratio of the O₂ gas pressure to the N₂ gas pressure is 18.1%. However, the gas composition in the chamber is not limited thereto as long as the ratio of the O₂ gas pressure to the N₂ gas pressure is not more than 20%. O₂ gas may be supplied as a source gas. In the foregoing embodiment, deposition is performed under a pressure of 0.7 Pa. However, the pressure in the deposition process is not limited to this pressure. The deposition process can be performed under an optimum pressure as appropriate.

For example, in the case where the AlON film is arranged on both of the front and back sides of the substrate, the sputtering deposition may be performed once for each of the front surface and the back surface of the substrate. In the case where an intermediate layer is interposed between the substrate and the AlON film, the intermediate layer may be formed on the substrate in advance.

In the case where the magnetron sputtering deposition system is used, the materials and the shapes of the backing plate and the cathode of the sputtering unit are not particularly limited. For example, nonmagnetic conductive materials may be used for the backing plate. Among them, metal materials such as copper having high electrical conductivity and heat conductivity are preferred. Stainless steel and other metals such as aluminium can be used for the cathode. The configuration of the magnetic field forming means for forming a magnetic field on the surface of the target is not limited to the foregoing embodiment. In the case where permanent magnets are used as the magnetic field forming means, the kind and the arrangement of permanent magnets can be determined as appropriate. For example, the north pole and the south pole of each permanent magnet may be reversed with respect to the forgoing embodiment. The material and the shape of the chamber are not also particularly limited. For example, the chamber can be formed of a metal material. Aluminium as in the foregoing embodiment and stainless steel are preferred in terms of workability such as weldability and machinability, corrosion resistance, and cost efficiency.

The material of the slot antenna, the number, shape and arrangement of slots, and the like in the ECR plasma generator are not particularly limited. For example, the material of the slot antenna may be any nonmagnetic metal such as stainless steel and brass in addition to aluminium. The slots may be arranged in two rows rather than in one row. The number of slots may be either odd or even. The slots may be arranged at different angles in a zigzag pattern. The material and the shape of the dielectric section are not also particularly limited. The dielectric section is preferably made of a material that has a low dielectric constant and that does not easily absorb microwaves. Preferred examples include quartz, aluminium oxide (alumina), and the like.

In the foregoing embodiment, ECR plasma is generated using microwaves at a frequency of 2.45 GHz. However, the frequency of microwaves is not limited to the 2.45 GHz band, and any frequency band in a range from 300 MHz to 100 GHz may be used. Examples of the frequency band in this range include 8.35 GHz, 1.98 GHz, and 915 MHz.

The material and the shape of the support plate are not particularly limited. In the foregoing embodiment, a refrigerant path and coolant are arranged as the cooling means for the support plate. However, the configuration of the cooling means for the support plate is not limited to the foregoing embodiment. The support plate may not have cooling means.

For the permanent magnets that form a magnetic field in front of the dielectric section (plasma generation region), the shape, kind, number, arrangement, and the like thereof are not particularly limited as long as the permanent magnets can produce ECR. For example, a single permanent magnet alone may be arranged, or a plurality of permanent magnets may be arranged in two or more rows.

Additional permanent magnets may be arranged so as to face the microwave plasma generation unit with the plasma generation region interposed therebetween. Specifically, permanent magnets may be arranged on the front wall of the chamber 8 in FIG. 2 so as to face the eight permanent magnets 45. Here, the additional permanent magnets are arranged so as to have the north pole on the front side and the south pole on the rear side. By doing so, the north pole of the eight permanent magnets 45 and the south pole of the additional permanent magnets face each other. Accordingly, ECR plasma P1 having higher directivity can be generated. Preferably, the additional permanent magnets are also provided with cooling means for suppressing temperature increase. In this case, for example, the support plate in the foregoing embodiment having a refrigerant path and coolant may be arranged on the rear side (the plasma generation region side) of the permanent magnets.

### Examples

Referring now to FIG. 1 and FIG. 2, transmittance experiments on film members produced using the magnetron sputtering deposition system 1 and the production method in the foregoing embodiment will be described. The reference signs denoting the members shown below correspond to those in FIG. 1 and FIG. 2. Table 1 and Table 2 show the production conditions, experiments and analysis results for the film members.

TABLE 1

| | | Example 1 | Example 2 | Example 3 | Example 4 | Example 5 | Example 6 |
|---|---|---|---|---|---|---|---|
| Substrate | | HC-PET | HC-PET | HC-PET | HC-PET | PEN | PEN |
| Gas barrier film | | AlON film | AlON film | AlON film | AlON film | AlON film | AlON film |
| | | (one side) | (one side) | (one side) | (one side) | (one side) | (both sides) |
| Target | | Al | Al | Al | Al | Al | Al |
| Pressure reached in the pressure reduction | | 0.015 | 0.015 | 0.008 | 0.008 | 0.015 | 0.015 |
| step [Pa] | | | | | | | |
| Pressure during Ar gas supply [Pa] | | 0.55 | 0.55 | 0.55 | 0.55 | 0.55 | 0.55 |
| Pressure during deposition (Ar + O₂ + N₂) [Pa] | | 0.7 | 0.7 | 0.7 | 0.7 | 0.7 | 0.7 |
| Ratio of O₂ gas pressure*¹ [%] | | 18.1 | 18.7 | 19.1 | 18.7 | 18.1 | 18.1 |
| ECR plasma during deposition | | Applied | Applied | Applied | Applied | Applied | Applied |
| Film thickness [nm] | | 60 | 60 | 60 | 60 | 60 | 60 |
| He transmittance ratio*² [%] | | 4.2 | 5.8 | 12 | 4 | 1.5 | 0.8 |
| Composition of AlON film | N 1s | 24.2 | 28.7 | 42.4 | 39.5 | 24.2 | 24.2 |
| ESCA (depth direction | O 1s | 27.3 | 25.4 | 7.2 | 11.8 | 27.3 | 27.3 |
| analysis) | Al 2p | 48.5 | 45.9 | 50.5 | 48.7 | 48.5 | 48.5 |

| | | Example 7 | Example 8 | Example 9 | Example 10 |
|---|---|---|---|---|---|
| Substrate | | PET | PEN with | PEN with | PEN with |
| | | | hydrocarbon | SiOₓ film | silazane film |
| | | | film | | |
| Gas barrier film | | AlON film | AlON film | AlON film | AlON film |
| | | (one side) | (one side) | (one side) | (one side) |
| Target | | Al | Al | Al | Al |
| Pressure reached in the pressure reduction | | 0.015 | 0.015 | 0.015 | 0.015 |
| step [Pa] | | | | | |
| Pressure during Ar gas supply [Pa] | | 0.55 | 0.55 | 0.55 | 0.55 |
| Pressure during deposition (Ar + O₂ + N₂)[Pa] | | 0.7 | 0.7 | 0.7 | 0.7 |
| Ratio of O₂ gas pressure*¹ [%] | | 18.1 | 18.1 | 18.1 | 18.1 |
| ECR plasma during deposition | | Applied | Applied | Applied | Applied |
| Film thickness [nm] | | 60 | 60 | 60 | 60 |
| He transmittance ratio*² [%] | | 3.2 | 1.4 | 1.3 | 0.8 |
| Composition of AlON film | N 1s | 24.2 | 24.2 | 24.2 | 24.2 |
| ESCA (depth direction | O 1s | 27.3 | 27.3 | 27.3 | 27.3 |
| analysis) | Al 2p | 48.5 | 48.5 | 48.5 | 48.5 |

*¹P_{O2}/P_{N2} × 100
*²Transmittance ratio where He transmittance of PEN film is set to 100%

TABLE 2

| | | Comparative | Comparative | Comparative | Comparative | Comparative | Comparative | Comparative |
|---|---|---|---|---|---|---|---|---|
| | | Example 1 | Example 2 | Example 3 | Example 4 | Example 5 | Example 6 | Example 7 |
| Substrate | | HC-PET | HC-PET | HC-PET | HC-PET | PEN | PET | PEN |
| Gas barrier film | | AlON film | AlON film | AlON film | — | — | — | SiOₓN_{y} film |
| | | (one side) | (one side) | (one side) | | | | (one side) |
| Target | | Al | Al | Al | — | — | — | Si |
| Pressure reached in the pressure reduction | | 0.015 | 0.015 | 0.015 | | | | — |
| step [Pa] | | | | | | | | |
| Pressure during Ar gas supply [Pa] | | 0.55 | 0.55 | 0.55 | | | | |
| Pressure during deposition (Ar + O₂ + N₂)[Pa] | | 0.7 | 0.7 | 0.7 | | | | |
| Ratio of O₂ gas pressure*¹ [%] | | 20.2 | 22.3 | 22.8 | | | | |
| ECR plasma during deposition | | Applied | Applied | Applied | | | | Not applied |
| Film thickness [nm] | | 60 | 60 | 60 | — | — | — | 50 |
| He transmittance ratio*² [%] | | 230.5 | 240 | 238.1 | 240 | 100 | 245 | 53 |
| Composition of AlON film | N 1s | 0.5 | 0.3 | 0 | — | — | — | — |
| ESCA (depth direction | O 1s | 61.2 | 60.7 | 61.1 | | | | |
| analysis) | Al 2p | 38.3 | 39.1 | 38.9 | | | | |

*¹P_{O2}/P_{N2} × 100
*²Transmittance ratio where He transmittance of PEN film isset to 100%

For deposition of a gas barrier film, first, the chamber 8 was evacuated so that the pressure reached the pressure reached in the pressure reduction step shown in the tables. Next, in the deposition step, Ar gas was supplied, and the pressure in the chamber 8 was set to the one shown in the tables. Then, the microwave plasma process was performed for 0.5 minutes with the output of the microwave oscillator 53 set to 1.2 kW for cleaning the surface of the substrate 20 and so forth. Afterwards, the output of the microwave oscillator 53 was turned off, and N₂ gas and O₂ gas were supplied at the flow rates regulated so that the reaction pressure during sputtering deposition and the ratio of the O₂ gas pressure (P_{O2}) to the N₂ gas pressure (P_{N2}) reached those shown in the tables. With the output of the microwave oscillator 53 set to 1.2 kW, voltage was applied to the cathode 33 under the following conditions: output of the DC pulse power source 35 (“RPG-100, Pulsed DC Plasma Generator” manufactured by MKS Instruments Japan) 2 kW; frequency 100 kHz, and pulse width 3056 ns. Sputtering deposition was thereby performed on the substrate 20 until the film thickness shown in the tables was achieved. For Comparative example 7, deposition was performed without applying ECR plasma P1 during sputtering deposition. In a case where deposition was performed with application of ECR plasma P1, the voltage during deposition reached 190 V (the voltage was automatically controlled by the DC pulse power source 35). Thus, compared with Comparative Example 7 in which deposition was performed without applying ECR plasma P1, the applied voltage was able to be reduced by about 20%.

The items in Table 1 and Table 2 will be explained. In Table 1 and Table 2, the “ratio of the O₂ gas pressure” refers to the ratio (P_{O2}/P_{N2}×100) of the O₂ gas pressure (P_{O2}) to the N₂ gas pressure (P_{N2}) in the chamber 8 during deposition. The “He transmittance ratio” refers to the transmittance ratio of each film member where the transmittance of the PEN film when He gas is passed through is 100%. The transmittance of He gas was measured in accordance with JIS K7126-1:2006, Appendix 2. The smaller the value of the He transmittance ratio, the higher the gas barrier characteristic.

The film thickness was measured as follows. First, a sample was prepared which had a gas barrier film deposited on a glass plate partially masked with a polyimide tape in advance. The polyimide tape was stripped off, and the deposited portion and the non-deposited portion were measured with a surface profiling measuring system (“DEKTAK 3030” manufactured by Sloan Technology Corp). The measurement value was considered as the thickness of the gas barrier film.

The substrates used are as follows. The HC-PET film was “KB film GSAB (thickness 188 μm)” manufactured by Kimoto Co., Ltd., the PEN film was “Teijin (registered trademark) Tetoron (registered trademark) Film Q65FA (thickness 200 μm)” manufactured by Teijin DuPont Films Japan Limited, and the PET film was “Lumirror (registered trademark) T60 (thickness 200 μm)” manufactured by Toray Industries, Inc. In Example 6, the gas barrier film was deposited on both surfaces of the substrate. Except for Example 6, in all the cases where the gas barrier film was deposited on a single side, the gas barrier film was deposited on a smooth surface side of the substrate.

In Comparative Example 4, the HC-PET film was used alone (without a gas barrier film). In Comparative Example 5, the PEN film was used alone (without a gas barrier film). In Comparative Example 6, the PET film was used alone (without a gas barrier film). The film in Comparative Example 7 is equivalent to a conventional film member in which a silicon oxynitride (SiOₓN_{y}) film is arranged on a PEN film.

In Example 8, a PEN film having a hydrocarbon film formed on the smooth surface side was used as a substrate. An AlON film was deposited on the surface of the hydrocarbon film. The hydrocarbon film was formed by plasma CVD using the magnetron sputtering deposition system 1 shown in FIG. 1 and FIG. 2 (without using the sputtering unit 3). Specifically, the chamber 8 was evacuated so that the pressure inside reached 0.02 Pa or less. Next, after Ar gas was supplied and the pressure in the chamber 8 was regulated to 0.5 Pa, the microwave plasma process was performed on a PEN film for 0.5 minutes with the output of the microwave oscillator 53 set to 1.0 kW. Afterward, the output of the microwave oscillator 53 was temporarily turned off, and acetylene gas and hydrogen gas in equal amounts were supplied so that the pressure in the chamber 8 was 0.6 Pa. With the output of the microwave oscillator 53 set to 1.0 kW, microwave plasma CVD was performed for one minute.

In Example 9, a PEN film having a SiOₓ film formed on the smooth surface side was used as a substrate. An AlON film was deposited on the surface of the SiOₓ film. The SiOₓ film was formed by plasma CVD in the same manner as in Example 8. Hexamethyldisiloxane (HMDSO manufactured by Tokyo Chemical Industry Co., Ltd.) was used as a reactant gas.

In Example 10, a PEN film having a silazane film formed on the smooth surface side was used as a substrate. An AlON film was formed on the surface of the silazane film. The silazane film was formed as follows. First, the microwave plasma process was performed on a PEN film under a pressure of 0.5 Pa for 0.5 minutes in the same manner as in Example 8. Next, the processed PEN film was exposed to the air to form a hydroxy group on the processed surface. A silazane (“AQUAMICA (registered trademark) NAX120-20” manufactured by AZ Electronic Materials) was then applied with a spin coater and dried at 80° C. for one day to form a silazane film of 0.3 μm in thickness.

As shown in Table 1 and Table 2, in Comparative Examples 1 to 3, a film was deposited in an atmosphere in which the ratio of the O₂ gas pressure exceeded 20%, and the He transmittance ratio of each film was almost the same as the He transmittance ratio of Comparative Example 4 in which only the substrate was used. By contrast, in Examples 1 to 10, a film was deposited in an atmosphere in which the ratio of the O₂ gas pressure was not more than 20%, the He transmittance ratio of each film was significantly smaller than those of the Comparative Examples 1 to 3 and Comparative Examples 4 to 6 in which only the substrate was used. The He transmittance ratios in Examples 1 to 10 were also smaller than that of Comparative Example 7 that is a conventional film member. The He transmittance ratios in Examples 5, 6, and 8 to 10 in which a PEN film was used as a substrate were smaller than the He transmittance ratios in Examples 1 to 4 and 7 in which a HC-PET film or a PET film was used as a substrate. Among these, in Example 6 in which an AlON film was formed on both of the front and back surfaces of the substrate and Example 10 in which an AlON film was formed on the silazane film, the He transmittance ratio was even smaller. As described above, it has been found that the film members in Examples 1 to 10 were very unlikely to allow He gas to pass through, that is, had a high gas barrier characteristic.

The AlON films in the film members of Examples 1 to 10 and Comparative Examples 1 to 3 were analyzed with an Electron Spectroscopy for Chemical Analysis (ESCA). The AlON films in Examples 1 to 10 all satisfied the composition: 39 at % to 55 at % of Al, 7 at % to 60 at % of O, and 1 at % to 50 at % of N. By contrast, the AlON films in Comparative Examples 1 to 3 each have an O content exceeding 60 at % and an N content less than 1 at %.

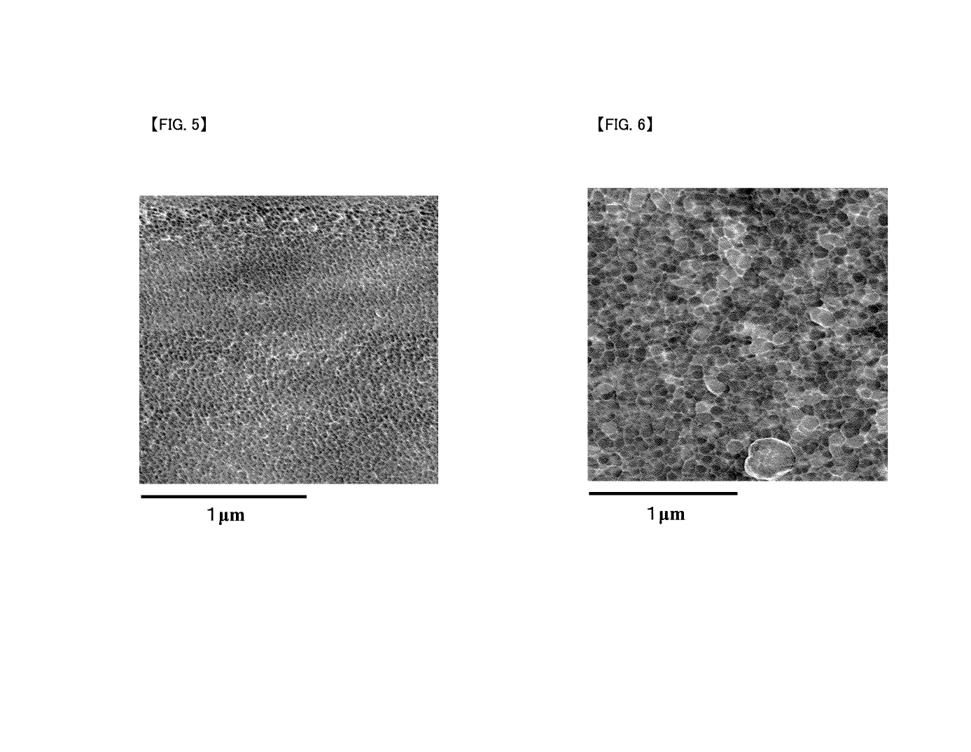

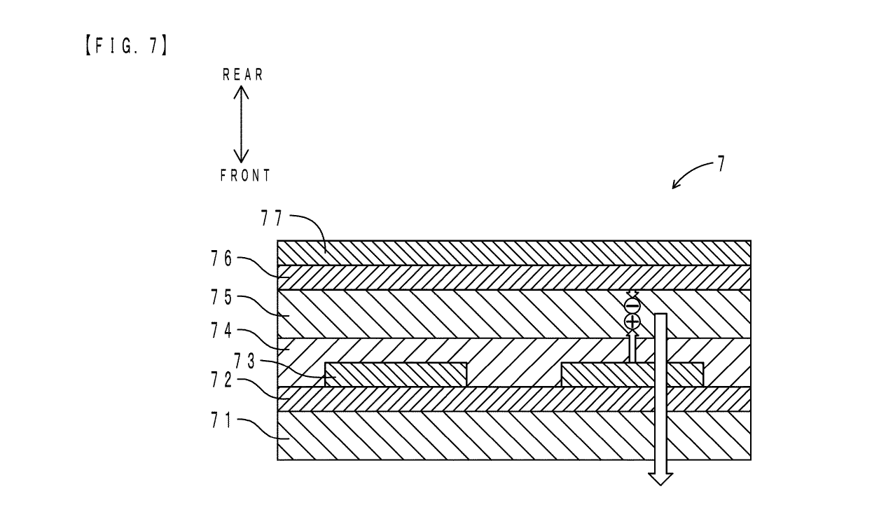

In addition, an AlON film was formed without activating the ECR plasma generator 4 in the magnetron sputtering deposition system 1 in the foregoing embodiment. In other words, an AlON film was formed without applying ECR plasma P1. The other production conditions were the same as in Example 1. The resulting film member was considered as Reference Example. The surfaces of the AlON films of Example 1 and Reference Example were observed with a scanning probe microscope (SPM). FIG. 5 shows an SPM image of Example 1. FIG. 6 shows an SPM image of Reference Example.

The comparison between FIG. 5 and FIG. 6 shows that the AlON film (FIG. 5) deposited with application of ECR plasma P1 is more fine-grained and uniform than the AlON film (FIG. 6) deposited without applying ECR plasma P1. Specifically, the particle diameter of the AlON film in Example 1 was around 40 nm, and the surface roughness was Ra=1.7 nm and Rz=21.7 nm. In contrast, the particle diameter of the AlON film of Reference Example greatly varied around 90 nm to 350 nm and the surface roughness was Ra=2.7 nm and Rz=53.0 nm.

### INDUSTRIAL APPLICABILITY

The film member according to the present invention is useful as a functional resin film for use, for example, in touch panels, displays, light emitting diode (LED) illumination, solar cells, and electronic paper.

1. A method for producing a film member including: a substrate formed of a resin film; and an aluminium oxynitride (AlON) film arranged on at least one of a front side and a back side of the substrate, the method characterized by comprising:
a pressure reduction step of arranging the substrate in a chamber of a sputtering deposition system such that the substrate faces a target made of aluminium and exhausting gas in the chamber to maintain a predetermined vacuum level in the chamber; and
a deposition step of introducing a source gas including nitrogen and a carrier gas into the chamber and sputtering the target with plasma generated by ionization of the carrier gas at a predetermined vacuum level in an atmosphere in which a ratio of an oxygen gas pressure to a nitrogen gas pressure in the chamber is not more than 20%, to form the aluminium oxynitride film which is composed of 39 at % to 55 at % of Al, 7 at % to 60 at % of O, and 1 at % to 50 at % of N on a deposition surface of the substrate.

2. The method for producing the film member according to claim 1, wherein
the sputtering deposition system includes the target and magnetic field forming means for forming a magnetic field on a surface of the target, and generates the plasma by magnetron discharge.

3. The method for producing the film member according to claim 2, wherein
the sputtering deposition system further includes an ECR plasma generator,
the ECR plasma generator includes:
a rectangular waveguide that transmits microwaves;
a slot antenna arranged on one surface of the rectangular waveguide and having a slot through which the microwaves pass;
a dielectric section arranged so as to cover the slot of the slot antenna and having a front surface on a plasma generation region side parallel to an incident direction of the microwaves from the slot;
a support plate arranged on a back surface of the dielectric section for supporting the dielectric section; and
a permanent magnet arranged on a back surface of the support plate for forming a magnetic field in the plasma generation region,
plasma is generated while electron cyclotron resonance (ECR) is produced with the microwaves propagating from the dielectric section into the magnetic field, and
in the deposition step, sputtering is performed with ECR plasma applied between the substrate and the target.

4. The method for producing the film member according to claim 1, wherein
a particle diameter of aluminium oxynitride constituting the aluminium oxynitride film is not more than 150 nm.

5. The method for producing the film member according to claim 1, wherein
the aluminium oxynitride film has a surface roughness in which an arithmetic mean roughness (Ra) is not more than 3 nm and the maximum height (Rz) is not more than 30 nm.
